(19) United States
(12) Patent Application Publication
(10) Pub. No.: US 2026/0171984 A1
(43) Pub. Date: Jun. 18, 2026

(54) RADIO-FREQUENCY POWER AMPLIFIER

(71) Applicant: SHENZHEN INSTITUTES OF ADVANCED TECHNOLOGY, Shenzhen (CN)

(72) Inventors: Xinwei RONG, Shenzhen (CN); Ye LI, Shenzhen (CN); Hairong ZHENG, Shenzhen (CN); Jifeng CHEN, Shenzhen (CN); Jiasheng WANG, Shenzhen (CN)

(73) Assignee: SHENZHEN INSTITUTES OF ADVANCED TECHNOLOGY, Shenzhen, GD (CN)

(21) Appl. No.: 19/127,671

(22) PCT Filed: Nov. 29, 2022
(86) PCT No.: PCT/CN2022/135078

§ 371 Date: May 6, 2025

(30) Foreign Application Priority Data
Nov. 18, 2022 (CN) 202211445087.4

(51) Int. Cl. H03F 3/189; H03F 1/52; H03F 1/56; H03F 3/20

(52) U.S. Cl. CPC H03F 3/189; H03F 1/52; H03F 1/565; H03F 3/20; H03F 2200/451

(57) ABSTRACT

Provided is a radio-frequency power amplifier. The radio-frequency power amplifier includes a direct current power module, an analog switch module, and a gate direct current path module. The direct current power module includes a first filter capacitor connected between an output terminal of the direct current power module and a ground terminal. The analog switch module includes an analog switch and a second filter capacitor. An input terminal of the analog switch is connected to the output terminal of the direct current power module. The second filter capacitor is connected between the input terminal of the analog switch and a ground terminal. The gate direct current path module is connected between an output terminal of the analog switch and a bias input terminal of a radio-frequency power amplification module.

This application claims priority to Chinese Patent Application No. 202211445087.4 filed with the China National Intellectual Property Administration (CNIPA) on Nov. 18, 2022, the disclosure of which is incorporated herein by reference in its entirety.

### TECHNICAL FIELD

The present application relates to the technical field of medical magnetic resonance imaging, for example, to a radio-frequency power amplifier.

### BACKGROUND

With the development of wireless technology, radio-frequency power amplifiers are widely applied in fields such as medical magnetic resonance imaging, and base stations, radar and electronic countermeasures for wireless communication. In magnetic resonance systems, ultra-short echo time (UTE) is generally required to be in the range of 8 μs to 500 μs, and the echo time in the systems is constrained by the turn-on or turn-off time of the radio-frequency power amplifier.

Currently, radio-frequency power amplifiers and bias circuits of the radio-frequency power amplifiers primarily inject low-frequency intermodulation distortion into the input section of an operational amplifier connected to the gate of a field-effect transistor to replace decoupling capacitors, so as to achieve decoupling of intermodulation distortion at a lower power level.

However, operational amplifiers which have weak driving capability for capacitors can easily lead to ringing phenomena, increase settling time and affect the transient response time of the radio-frequency power amplifier, and lead to a decreased ability of being injected with the intermodulation distortion generated by the high-power amplifiers, resulting in serious intermodulation distortion issues in the output signal of the radio-frequency power amplifier.

### SUMMARY

The present application provides a radio-frequency power amplifier.

The radio-frequency power amplifier provided by the present application includes a direct current power module, an analog switch module, a gate direct current path module, and a radio-frequency power amplification module. The direct current power module includes a first filter capacitor connected between an output terminal of the direct current power module and a ground terminal. The output terminal of the direct current power module outputs a direct current voltage. The analog switch module includes an analog switch and a second filter capacitor. An input terminal of the analog switch is connected to the output terminal of the direct current power module. The second filter capacitor is connected between the input terminal of the analog switch and a ground terminal. The capacitance value of the second filter capacitor is less than the capacitance value of the first filter capacitor. The gate direct current path module is connected between an output terminal of the analog switch and a bias input terminal of a radio-frequency power amplification module and is configured to process a signal output from the analog switch module and output a bias voltage to the radio-frequency power amplification module. The gate direct current path module and the analog switch module are disposed adjacent to the radio-frequency power amplification module. The radio-frequency power amplification module is configured to amplify a radio frequency pulse signal and output an amplified radio frequency pulse signal.

It is to be understood that the content described in this part is neither intended to identify key or important features of the embodiments of the present application nor intended to limit the scope of the present application. Other features of the present application are apparent from the description provided hereinafter.

### BRIEF DESCRIPTION OF DRAWINGS

FIG. 1 is a schematic structural diagram of a radio-frequency power amplifier according to the present application.

FIG. 2 is a schematic structural diagram of another radio-frequency power amplifier according to the present application.

FIG. 3 is a schematic structural diagram of another radio-frequency power amplifier according to the present application.

FIG. 4 is a schematic structural diagram of another radio-frequency power amplifier according to the present application.

### DETAILED DESCRIPTION

It is to be noted that terms such as “first” and “second” in the description, claims, and drawings of the present application are used to distinguish between similar objects and are not necessarily used to describe a particular order or sequence. It should be understood that the data used in this manner is interchangeable where appropriate so that the embodiments of the present application described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

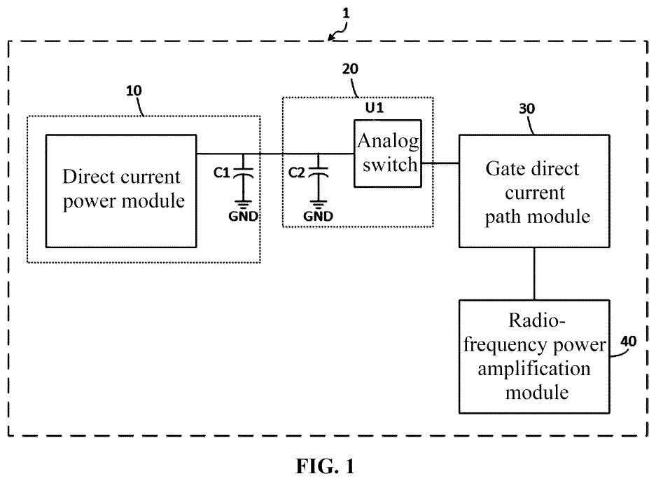

FIG. 1 is a schematic structural diagram of a radio-frequency power amplifier according to the present application. The embodiment is applicable to scenarios involving radio-frequency power amplification.

As shown in FIG. 1, the radio-frequency power amplifier 1 includes a direct current power module 10, an analog switch module 20, a gate direct current path module 30, and a radio-frequency power amplification module 40.

The direct current power module 10 includes a first filter capacitor C1 connected between an output terminal of the direct current power module 10 and a ground terminal GND. The first filter capacitor C1 serves as an output filter capacitor for the direct current power module 10. The output terminal of the direct current power module 10 outputs a direct current voltage.

The direct current power module 10 may be a direct current voltage-stabilized power module with temperature compensation functionality, adjustable voltage, and low noise. In an embodiment, the temperature compensation functionality of the direct current power module 10 may be used to compensate for drift caused by temperature variations in a radio-frequency power amplification module 40. The noise range of the direct current power module 10 may be between 0.8 μVrms and 20 μVrms. The model of the direct current power module 10 may vary. Exemplarily, the direct current power module 10 may be an LP38798, an LT3045, or similar.

The analog switch module 20 includes an analog switch U1 and a second filter capacitor C2. An input terminal of the analog switch U1 is connected to the output terminal of the direct current power module 10. The second filter capacitor C2 is connected between the input terminal of the analog switch U1 and a ground terminal GND. The capacitance value of the second filter capacitor C2 is less than the capacitance value of the first filter capacitor C1. The second filter capacitor C2 is disposed closer to the input terminal of the analog switch U1 than the first filter capacitor C1. In other words, the second filter capacitor C2 is connected in parallel with the first filter capacitor C1, and the input terminal of the analog switch U1 and the direct current power module 10 share the second filter capacitor C2. Due to differences in the self-resonant frequencies of actual capacitors, the parallel connection of the first filter capacitor C1 and the second filter capacitor C2 achieves low impedance from hundreds of hertz to several megahertz, thereby enhancing the filtering effect.

An enable terminal of the analog switch U1 is used to control the connection or disconnection of the voltage signal output from the direct current power module 10. The analog switch U1 may be an integrated circuit with normally open and normally closed functions or a circuit which is constructed from discrete transistors and has normally open and normally closed functions. Exemplarily, the analog switch U1 may be a TMU6219, an ADG1419, an ADG1459, an ADG849, or a switch with similar functionality constructed from transistors. The turn-on or turn-off time of the analog switch U1 affects the turn-on or turn-off time of the radio-frequency power amplifier 1, and the on-resistance and peak current of the analog switch U1 affect the charging transient response time of the radio-frequency power amplifier 1. The analog switch U1 exhibits good radio frequency performance with low insertion loss, providing an effective path for spurs and low-frequency intermodulation distortion to the second filter capacitor C2.

In the embodiment of the present application, the introduction of a new second filter capacitor C2 can achieve decoupling of low-frequency intermodulation distortion. For example, since all capacitors have parasitic inductance, larger capacitance values typically correspond to greater parasitic inductance. This parasitic inductance, in series with the capacitance, forms an LCR resonant circuit, where L is the inductance related to lead length, R is the lead resistance, and C is the capacitance. The resonant circuit has a resonant frequency at which impedance is minimized. As the operating frequency of the radio-frequency power amplifier varies, the characteristics of the capacitor change accordingly. When the operating frequency is below the resonant frequency, the capacitor generally exhibits capacitive behavior; when the operating frequency is above the resonant frequency, the capacitor generally exhibits inductive behavior, at which point the capacitor loses its decoupling function. The capacitance value is generally selected based on the resonant frequency of the capacitor. Capacitors with different capacitance values and packages may filter signals of different frequencies. The capacitance value of the second filter capacitor C2 is configured to be less than that of the first filter capacitor C1 so that the first filter capacitor C1 can filter waves from tens of hertz (Hz) to hundreds of kilohertz (kHz), while the second filter capacitor C2 can filter waves at and below approximately one-tenth of the center operating frequency of the radio frequency pulse signal. Exemplarily, when the center operating frequency of the radio frequency pulse signal is 210 MHz, the second filter capacitor C2 is used to filter waves from approximately 1 MHz to 20 MHz.

The turn-on or turn-off time of the radio-frequency power amplifier 1 is determined by the primary charging and discharging time constants of the transient response of the radio-frequency power amplifier 1 and the switching speed of the analog switch U1. Therefore, when the second filter capacitor C2 is disposed at the output terminal of the analog switch U1, due to the on-resistance of the analog switch U1, the charging time increases, thereby increasing the primary charging time constant of the transient response of the radio-frequency power amplifier 1. When the second filter capacitor C2 is disposed at the input terminal of the analog switch U1, the transient response time of the radio-frequency power amplifier 1 can be shortened, enabling rapid turn-on or turn-off of the radio-frequency power amplifier 1.

The gate direct current path module 30 is connected between an output terminal of the analog switch U1 and a bias input terminal of a radio-frequency power amplification module 40 and is configured to process a signal output from the analog switch module 20 and output a bias voltage to the radio-frequency power amplification module 40. The radio-frequency power amplification module 40 is configured to amplify a radio frequency pulse signal and output an amplified radio frequency pulse signal. The gate direct current path module 30 is used to ensure that the radio-frequency power amplifier 1 does not experience self-oscillation during operation and reduce ringing phenomena in the radio-frequency power amplification module 40.

The radio frequency pulse signal includes pulses of a fixed sequence and pulses of a variable sequence. In other words, the direct current power module 10, the analog switch module 20, and the gate direct current path module 30 constitute a direct current bias circuit for the radio-frequency power amplifier 1. The direct current bias circuit is applicable not only to radio-frequency power amplifiers with narrow pulse modulation of fixed sequences but also to radio-frequency power amplifiers with pulse modulation of variable sequences featuring variable pulse widths and periods, specifically, UTE sequences in magnetic resonance systems; and moreover, the direct current bias circuit is applicable to commonly used radio-frequency power amplifiers.

The operating process of the radio-frequency power amplifier 1 is as follows: The direct current power module 10 adjusts the output direct current voltage based on the requirements of the radio-frequency power amplification module 40, provides an appropriate quiescent operating current for the radio-frequency power amplification module 40, and determines the direct current voltage for an appropriate quiescent operating point. After the first filter capacitor C1 and the second filter capacitor C2 filter radio frequency pulse signals of different operating frequencies, the filtered signals are input to the analog switch U1. A pulse signal at the enable terminal of the analog switch U1 controls the turn-on and turn-off of the analog switch U1, thereby controlling the turn-on and turn-off of the radio frequency pulse signal. When the analog switch U1 is turned on, the gate direct current path module 30 processes the signal output from the analog switch module 20 and outputs a bias voltage to the radio-frequency power amplification module 40. The gate direct current path module 30 and the analog switch module 20 are disposed close to the radio-frequency power amplification module 40. The radio-frequency power amplification module 40 amplifies the radio frequency pulse signal and outputs the amplified signal.

After the radio frequency pulse signal passes through the radio-frequency power amplification module 40, intermodulation distortion and spurs generated due to a nonlinear effect and a memory effect are directed through the gate direct current path module 30 to the analog switch U1. Low-frequency intermodulation distortion and spurs are decoupled by the first filter capacitor C1 and the second filter capacitor C2.

For a generated radio frequency pulse modulation signal with output power near the P1dB compression point, the nonlinear effect and the memory effect occur. The process is akin to AM modulation, where the modulation signal is a baseband pulse signal. AM modulation shifts the single-sideband spectrum of the baseband signal to the radio frequency carrier and produces two symmetrical sidebands, while radio frequency pulse modulation generates more sidebands and spurs.

The Fourier transform of the radio frequency pulse modulation signal may be expressed as follows:

$${u}_{p} ( t ) = \frac{τ}{T} {\sum }_{n = - ∞}^{∞} S a ( \frac{n Ω τ}{2} ) {e}^{j ( {ω}_{c} + n Ω ) t} .$$

In the formula, T and T denote the pulse width and pulse period of the radio frequency pulse signal, respectively; Ω=2π/T and ω_{c} denote the repetition frequency and carrier frequency of the radio frequency pulse signal, respectively; and n denotes any integer.

From this Fourier transform, it can be seen that the frequency component contained in the radio frequency pulse signal is ω_{c}+nΩ, and theoretically, an infinite number of frequency components are contained. Since the signal is periodic, its spectrum is discrete, the frequency spacing between adjacent spectral lines is Ω, and the Sa(x) function determines the amplitude of each spectral line.

For multiple discrete spectra, subjected to the nonlinear effect and the memory effect of a high-power radio frequency amplifier, more harmonics, intermodulation distortion, and spurs at various frequency points are produced, all of which are undesired interference signals. Variable pulse widths and periods cause changes in the frequency bands of intermodulation distortion and spurs generated by the radio-frequency power amplifier. Decoupling through the first filter capacitor C1 and the second filter capacitor C2 can reduce the intermodulation distortion and spurs in the output radio frequency pulse signal.

In the embodiment of the present application, the on-resistance and peak current of the analog switch affect the transient response time of the radio-frequency power amplifier. Therefore, the second filter capacitor is provided and positioned at the input terminal of the analog switch so that the decoupling capacitance at the output terminal of the analog switch can be reduced. Thus, the transient response time of the radio-frequency power amplifier can be shortened, and rapid turn-on or turn-off of the radio-frequency power amplifier is achieved. The capacitance value of the second filter capacitor is configured to be less than that of the first filter capacitor so that the first filter capacitor and the second filter capacitor can filter waves of different frequencies and intermodulation distortion and spurs in the radio frequency output signal can be reduced.

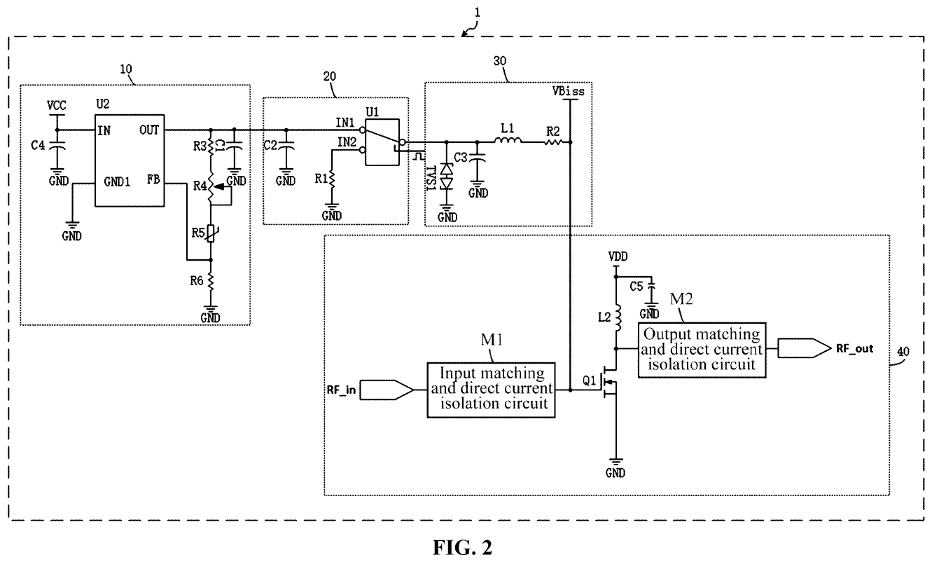

FIG. 2 is a schematic structural diagram of another radio-frequency power amplifier according to the present application.

As shown in FIG. 2, in an embodiment, the capacitance value of the first filter capacitor C1 is 10 to 100 times the capacitance value of the second filter capacitor C2. By setting the capacitance value of the first filter capacitor C1 to be 10 to 100 times the capacitance value of the second filter capacitor C2, the filtering effect can be improved.

The direct current power module 10 includes a linear voltage regulator chip U2, an input filter capacitor C4, a third resistor R3, a fourth resistor R4, a fifth resistor R5, and a sixth resistor R6. An input terminal IN of the linear voltage regulator chip U2 is connected to a first power supply VCC, and an output terminal OUT of the linear voltage regulator chip U2 is connected to the first filter capacitor C1. The input filter capacitor C4 is connected to the input terminal of the linear voltage regulator chip U2. The third resistor R3, the fourth resistor R4, the fifth resistor R5, and the sixth resistor R6 are connected in series between the output terminal OUT of the linear voltage regulator chip U2 and a ground terminal GND. A common connection point of the fifth resistor R5 and the sixth resistor R6 is connected to a feedback input terminal FB of the linear voltage regulator chip U2. The fourth resistor R4 is an adjustable resistor, and the fifth resistor R5 is a thermistor. A ground terminal GND1 of the linear voltage regulator chip U2 is grounded.

The output voltage of the linear voltage regulator chip U2 is as follows: Vout=Vref*(1+(R3+R4+R5)/R6), where Vref denotes an internal reference voltage value of the linear voltage regulator chip U2. The third resistor R3 is a fixed resistor. The fourth resistor R4 is an adjustable resistor used to adjust the direct current output voltage to meet the bias voltage requirements of the field-effect transistor in the radio-frequency power amplification module 40. The fifth resistor R5 is a thermistor. By using a negative temperature coefficient thermistor based on the temperature coefficient of the radio-frequency power amplifier 1, variations in current due to temperature changes can be reduced, thereby ensuring the stability of the output current and meeting the stability requirements of the quiescent operating current of the field-effect transistor.

The analog switch module 20 also includes a first resistor R1. The input terminal of the analog switch U1 includes a first input terminal IN1 and a second input terminal IN2. The first input terminal IN1 of the analog switch U1 is connected to the output terminal of the direct current power module 10. The second filter capacitor C2 is connected between the first input terminal IN1 of the analog switch U1 and the ground terminal GND. The first resistor R1 is connected between the second input terminal IN2 of the analog switch U1 and a ground terminal GND. The first resistor R1 serves as a discharge resistor.

In an embodiment, for different models of the radio-frequency power amplifier 1, a second end of the first resistor R1 may be grounded or connected to a negative power supply. Exemplarily, when the radio-frequency power amplifier 1 is composed of gallium nitride (GaN), the second end of the first resistor R1 is connected to a negative power supply for turn-off. A pulse signal at the enable terminal of the analog switch U1 controls the analog switch U1 to connect to the direct current power module 10 to turn on the radio frequency pulse signal or controls the analog switch U1 to connect to the first resistor R1 to turn off the radio frequency pulse signal via ground. The turn-on or turn-off time of the analog switch U1 affects the turn-on or turn-off time of the radio-frequency power amplifier 1, and the on-resistance and peak current of the analog switch U1 affect the transient response time of charging the input capacitance of the field-effect transistor. After the analog switch U1 is turned off, the input capacitance of the field-effect transistor is discharged through the first resistor R1, and the transient response time of discharging the input capacitance affects the turn-off time of the field-effect transistor. The turn-on time of the analog switch U1 and the charging time of the input capacitance of the field-effect transistor are referred to as the turn-on time of the radio-frequency power amplifier 1 based on the field-effect transistor, and the turn-off time of the analog switch U1 and the discharge time of the input capacitance of the field-effect transistor are referred to as the turn-off time of the radio-frequency power amplifier 1.

The gate direct current path module 30 includes a second resistor R2, a first inductor L1, a decoupling capacitor C3, and an overvoltage protection diode TVS1. A first end of the first inductor L1 is connected to the output terminal of the analog switch U1, a second end of the first inductor L1 is connected to a first end of the second resistor R2, and a second end of the second resistor R2 is connected to the bias input terminal. The overvoltage protection diode TVS1 is connected to the first end of the first inductor L1. A first end of the decoupling capacitor C3 is connected between the overvoltage protection diode TVS1 and the first end of the first inductor L1, and a second end of the decoupling capacitor C3 is connected to a ground terminal GND.

The second resistor R2 serves as a stabilizing resistor. The combination of the second resistor R2, the first inductor L1, and the decoupling capacitor C3 can ensure that the radio-frequency power amplifier 1 does not experience self-oscillation during operation. Additionally, the second resistor R2 provides damping during the transient response of the field-effect transistor, reducing ringing at the gate during the conduction process of the field-effect transistor. At the center operating frequency of the radio frequency pulse signal, the first inductor L1 attenuates part of the energy, and the remaining radio frequency energy is decoupled by using the decoupling capacitor C3. Intermodulation distortion and harmonics generated due to the nonlinear effect and the memory effect in the radio-frequency power amplifier 1, as well as the high-frequency energy, are also decoupled by the decoupling capacitor C3. The decoupling capacitor C3 is selected based on the center operating frequency of the radio frequency pulse signal. The capacitance value is relatively low, typically on the order of picofarads (pF). The capacitance value of the decoupling capacitor C3 is less than that of the first filter capacitor C1, which is determined primarily by the center operating frequency of the radio frequency pulse signal. For lower frequency bands generated by the nonlinear effect and the memory effect, these bands are decoupled by the second filter capacitor C2 through the analog switch U1. The capacitance value of the second filter capacitor C2 is relatively large, commonly on the order of microfarads (pF), thereby reducing the overall intermodulation distortion of the radio frequency pulse signal. Due to the bandwidth (3 dB) limitation of the analog switch U1, the center operating frequency of the radio frequency pulse signal is typically higher than the bandwidth of the analog switch U1. When the center operating frequency of the radio frequency pulse signal falls within the bandwidth of the analog switch U1, the decoupling capacitor C3 may be omitted. In this case, decoupling is handled by the first filter capacitor C1 and the second filter capacitor C2, and the transient response time is further improved.

The second end of the second resistor R2 is also connected to a third power supply VBiss.

The radio-frequency power amplification module 40 includes an input matching and direct current isolation circuit M1, an output matching and direct current isolation circuit M2, a field-effect transistor Q1, and a second inductor L2. The input matching and direct current isolation circuit M1 is connected between a radio frequency pulse signal input terminal RF_in and a gate of the field-effect transistor Q1. The second inductor L2 is connected between a first electrode of the field-effect transistor Q1 and a second power supply VDD. The output matching and direct current isolation circuit M2 is connected between a radio frequency pulse signal output terminal RF_out and the first electrode of the field-effect transistor Q1. A second electrode of the field-effect transistor Q1 is connected to a ground terminal GND. The gate of the field-effect transistor Q1 serves as the bias input terminal. The second inductor L2 is a choke inductor.

The radio-frequency power amplification module 40 also includes a fifth filter capacitor C5. The fifth filter capacitor C5 filters noise from the second power supply VDD so that the output of the second power supply VDD is more stable. The fifth filter capacitor C5 is connected between the second power supply VDD and a ground terminal GND.

The input matching and direct current isolation circuit M1 matches the radio frequency input signal with the field-effect transistor Q1 in the operating frequency band and isolates the direct current bias at the gate of the field-effect transistor Q1. The output matching and direct current isolation circuit M2 matches the radio frequency output signal with the output of the field-effect transistor Q1 and isolates the second power supply VDD connected to the second electrode of the field-effect transistor Q1.

The second power supply VDD of the field-effect transistor is typically high, and the overvoltage protection diode TVS1 ensures that the gate of the field-effect transistor remains at a safe voltage. In radio-frequency power amplifiers with kilowatt-level power, the parasitic capacitance of the field-effect transistor cannot be ignored. The input capacitance (Ciss) is large, generating spurs and harmonics with high power, and in this case, using an operational amplifier to inject current for decoupling at the gate input is impractical; and instead, capacitors are typically used for decoupling to reduce spurs and harmonics in the output.

The input capacitance Ciss of the field-effect transistor Q1 is as follows: Ciss=Cgs+Cgd, where Cgs denotes the parasitic capacitance between the gate and source, and Cgd denotes the parasitic capacitance between the gate and drain. The primary charging time constant of the transient response of the radio-frequency power amplifier 1 is as follows: τ1=R2*Ciss, and τ4=Ru2*C2, where Ru2 denotes the on-resistance of the analog switch U1, typically less than a few ohms. The primary discharging time constant of the transient response of the radio-frequency power amplifier 1 is as follows: τ2=(R1+R2)*Ciss, and τ3=R1*C3. The turn-on or turn-off time of the radio-frequency power amplifier 1 is determined according to the charging and discharging time constants and the switching speed of the analog switch U1. The total capacitance of the first filter capacitor C1 and the second filter capacitor C2 is significantly greater than the input capacitance of the field-effect transistor and the decoupling capacitor C3. By placing the second filter capacitor C2 before the analog switch U1, compared to the case of conventionally placing the filter capacitor after the analog switch U1, the turn-on or turn-off time is greatly improved. The primary charging time constant changes from Ru2*(C2+C3) to Ru2*C2, and the difference in transient response time may be observed on an oscilloscope. On an oscilloscope, from the terminal of the fifth filter capacitor C5, a reduction in the envelope amplitude of the spurious AM-modulated signal can be observed clearly in the case where the second filter capacitor C2 is added before the analog switch U1 comparing with the case where the second filter capacitor C2 is absent. Alternatively, a reduction in the power of spurious signals at the radio frequency pulse signal output terminal RF_out can be observed by using a spectrum analyzer and an attenuator. A short turn-on or turn-off time of the radio-frequency power amplifier is beneficial for transmitting hard radio frequency pulses. Conventional radio-frequency power amplifiers have turn-on or turn-off times of 10 μs to 20 μs, which do not meet the requirements of ultra-short echo time of 8 μs to 500 μs in magnetic resonance systems. The turn-on or turn-off time of the radio-frequency power amplifier in the present application is 40 ns to 300 ns, meeting the requirements for transmitting hard radio frequency pulses in UTE sequences and other functional pulse sequences.

In an embodiment, the second filter capacitor C2 is disposed adjacent to the field-effect transistor Q1. Positioning the second filter capacitor C2 adjacent to the field-effect transistor Q1 can reduce the impact of PCB routing and enhance the decoupling performance of the second filter capacitor C2.

In the embodiments of the present application, the high-power radio-frequency amplifier uses a field-effect transistor model MRFX1K80N. When the center operating frequency of the radio frequency pulse signal is 210 MHz, the capacitance value of the decoupling capacitor C3 is typically 510 pF, the capacitance value of the second filter capacitor C2 is typically 1 μF, and the capacitance value of the first filter capacitor C1 is typically 10 μF. The second resistor R2 is 6.2 ohms. The first inductor L1 is 22 nH. The first resistor R1 is 100 ohms. The second power supply VDD is 75 V. The saturated output power of the radio frequency pulse signal is 2400 W. The turn-on or turn-off time of the radio-frequency power amplifier is 40 ns to 300 ns. Thus, the requirements for transmitting hard radio frequency pulses in UTE sequences are met. The embodiments of the present application are verified through experiments. A radio-frequency power amplifier with a center operating frequency of 210 MHz and a P1dB output power of 2 kW is tested, and for an AM-modulated signal which has the maximum amplitude of 2.9 MHz in the maximum low-frequency band in the output of the radio-frequency power amplifier and is obtained by using a pulse modulation signal with a period of 100 ms and a pulse width of 200 μs, after setting the second filter capacitor of 1 pF at the input terminal of the analog switch, the output amplitude of the AM-modulated signal decreases from −43 dBc to −50 dBc as detected by a spectrum analyzer at the output terminal; for the AM-modulated signal which has a period of 1 s and a pulse width of 1 ms and whose the maximum amplitude of the intermodulation frequency is 7.3 MHz, the output is below −51 dBc after the second filter capacitor is added. For the low-frequency intermodulation signal which varies with the period and the pulse width, an improvement of more than 6 dB can be achieved using the method in this example.

The embodiments of the present application can be applied to pulse power amplifiers with variable sequences, enabling rapid turn-on or turn-off of pulse power amplifiers with variable sequences; and particularly for ultra-short echo time sequences in magnetic resonance systems, the on-resistance and peak current of the analog switch affect the transient response time of the radio-frequency power amplifier. Therefore, providing the second filter capacitor and positioning it at the input terminal of the analog switch can reduce the decoupling capacitance at the output terminal of the analog switch. Thus, the transient response time of the radio-frequency power amplifier can be shortened, and rapid turn-on or turn-off of the radio-frequency power amplifier is achieved. The capacitance value of the second filter capacitor is configured to be less than that of the first filter capacitor so that the first filter capacitor and the second filter capacitor can filter waves of different frequencies, and intermodulation distortion in the radio frequency output signal is reduced. The decoupling capacitor can filter residual radio frequency energy at the center operating frequency of the radio frequency pulse signal and reduces high-frequency energy from intermodulation distortion and harmonics caused by the nonlinear effect and the memory effect. The fourth resistor is configured to be an adjustable resistor so that the output voltage of the direct current power module can be adjusted to meet the bias voltage requirements of the gate of the field-effect transistor. The fifth resistor is configured to be a thermistor so that drift due to temperature variations in the field-effect transistor can be reduced, thereby ensuring the stability of the output current. The combination of the second resistor, the first inductor, and the decoupling capacitor can ensure stable operation of the radio-frequency power amplifier across the full frequency band without self-oscillation, and thus ringing is reduced at the gate of the field-effect transistor. The turn-on or turn-off time of the radio-frequency power amplifier in the present application is 40 ns to 300 ns, meeting the requirements of ultra-short echo time sequences in magnetic resonance and also applicable to commonly used radio-frequency power amplifiers.

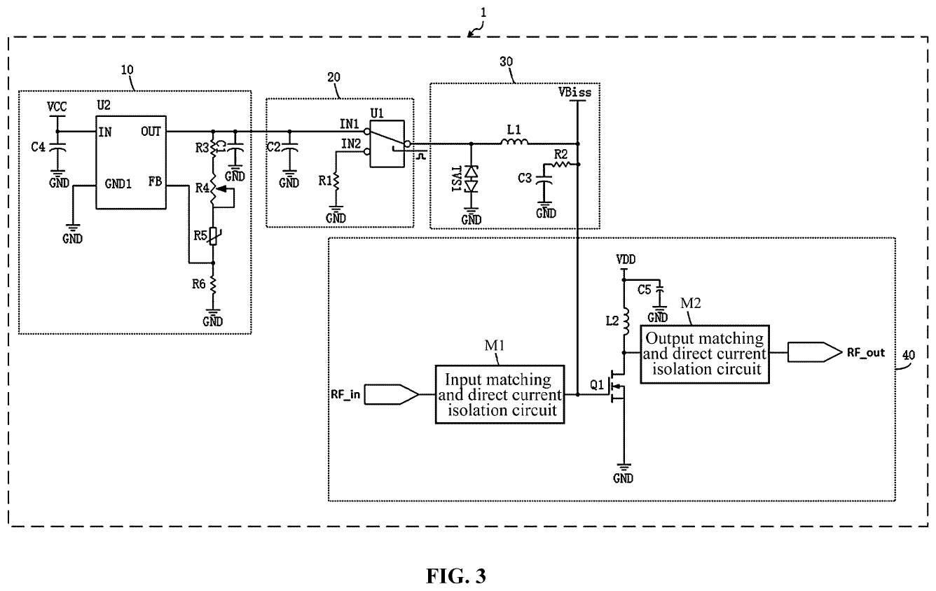

FIG. 3 is a schematic structural diagram of another radio-frequency power amplifier according to the present application.

As shown in FIG. 3, the gate direct current path module 30 includes a second resistor R2, a first inductor L1, a decoupling capacitor C3, and an overvoltage protection diode TVS1. A first end of the first inductor L1 is connected to the output terminal of the analog switch U1, a second end of the first inductor L1 is connected to a first end of the second resistor R2, and a second end of the second resistor R2 is connected to the bias input terminal. The overvoltage protection diode TVS1 is connected to the first end of the first inductor L1. The decoupling capacitor C3 is connected between a ground terminal GND and the first end of the second resistor R2, and the second end of the second resistor R2 is connected to the bias input terminal to achieve stable decoupling.

In an embodiment, the direct current power module 10, the analog switch module 20, and the radio-frequency power amplification module 40 in FIG. 3 are illustrated as including the structures shown in FIG. 2 as an example. This radio-frequency power amplifier 1 possesses the beneficial effects of any of the embodiments of the present application described above.

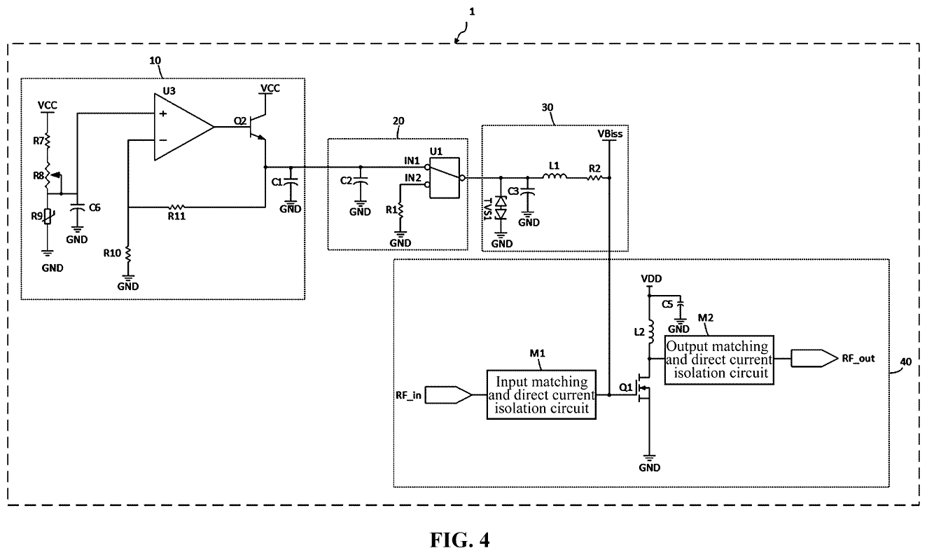

FIG. 4 is a schematic structural diagram of another radio-frequency power amplifier according to the present application.

As shown in FIG. 4, the direct current power module 10 includes an operational amplifier U3, a first input filter capacitor C6, a transistor Q2, a seventh resistor R7, an eighth resistor R8, a ninth resistor R9, a tenth resistor R10, and an eleventh resistor R11. The first input filter capacitor C6 is connected to a non-inverting input terminal IN+ of the operational amplifier U3. The seventh resistor R7, the eighth resistor R8, and the ninth resistor R9 are connected in series between a first power supply VCC and a ground terminal GND, and a common connection point of the eighth resistor R8 and the ninth resistor R9 is electrically connected to the non-inverting input terminal IN+ of the operational amplifier U3 to provide a reference voltage to the non-inverting input terminal IN+ of the operational amplifier U3. The eighth resistor R8 is an adjustable resistor, and the ninth resistor R9 is a thermistor. The tenth resistor R10 is connected between an inverting input terminal IN− of the operational amplifier U3 and a ground terminal GND. The eleventh resistor R11 is connected between a collector of the transistor Q2 and a first end of the tenth resistor R10. Abase of the transistor Q2 is connected to an output terminal of the operational amplifier U3, the collector of the transistor Q2 is connected to the first power supply VCC, and an emitter of the transistor Q2 is connected to the first filter capacitor C1.

In the embodiments of the present application, adding a transistor to an operational amplifier (without requiring high slew rate or bandwidth) can enhance the drive current, thereby forming a low-noise and low-cost direct current power module 10.

In an embodiment, the analog switch module 20, the gate direct current path module 30, and the radio-frequency power amplification module 40 in FIG. 4 are illustrated as including the structures shown in FIG. 2 as an example. This radio-frequency power amplifier 1 possesses the beneficial effects of any of the embodiments of the present application described above.

It is to be understood by those skilled in the art that various modifications, combinations, sub-combinations, and substitutions may be performed according to design requirements and other factors.

What is claimed is:

1. A radio-frequency power amplifier, comprising:
a direct current power module, wherein the direct current power module comprises a first filter capacitor, the first filter capacitor is connected between an output terminal of the direct current power module and a ground terminal, and the output terminal of the direct current power module outputs a direct current voltage;
an analog switch module, wherein the analog switch module comprises an analog switch and a second filter capacitor, an input terminal of the analog switch is connected to the output terminal of the direct current power module, and the second filter capacitor is connected between the input terminal of the analog switch and a ground terminal, wherein a capacitance value of the second filter capacitor is less than a capacitance value of the first filter capacitor; and
a gate direct current path module, wherein the gate direct current path module is connected between an output terminal of the analog switch and a bias input terminal of a radio-frequency power amplification module and is configured to process a signal output from the analog switch module and output a bias voltage to the radio-frequency power amplification module;
wherein the gate direct current path module and the analog switch module are disposed adjacent to the radio-frequency power amplification module, and the radio-frequency power amplification module is configured to amplify a radio frequency pulse signal and output an amplified radio frequency pulse signal.

2. The radio-frequency power amplifier according to claim 1, wherein the capacitance value of the first filter capacitor is 10 to 100 times the capacitance value of the second filter capacitor.

3. The radio-frequency power amplifier according to claim 1, wherein the analog switch module further comprises a first resistor; and
the input terminal of the analog switch comprises a first input terminal and a second input terminal, the first input terminal of the analog switch is connected to the output terminal of the direct current power module, the second filter capacitor is connected between the first input terminal of the analog switch and the ground terminal, and the first resistor is connected between the second input terminal of the analog switch and a ground terminal.

4. The radio-frequency power amplifier according to claim 1, wherein the gate direct current path module comprises a second resistor, a first inductor, a decoupling capacitor, and an overvoltage protection diode;
a first end of the first inductor is connected to the output terminal of the analog switch, a second end of the first inductor is connected to a first end of the second resistor, and a second end of the second resistor is connected to the bias input terminal; and
the overvoltage protection diode is connected to the first end of the first inductor, a first end of the decoupling capacitor is connected between the overvoltage protection diode and the first end of the first inductor, and a second end of the decoupling capacitor is connected to a ground terminal.

5. The radio-frequency power amplifier according to claim 1, wherein the gate direct current path module comprises a second resistor, a first inductor, a decoupling capacitor, and an overvoltage protection diode;
a first end of the first inductor is connected to the output terminal of the analog switch, a second end of the first inductor is connected to a second end of the second resistor, and a second end of the second resistor is connected to the bias input terminal;
the overvoltage protection diode is connected to the first end of the first inductor; and
the decoupling capacitor is connected between a ground terminal and the first end of the second resistor, and the second end of the second resistor is connected to the bias input terminal.

6. The radio-frequency power amplifier according to claim 4, wherein a capacitance value of the decoupling capacitor is less than the capacitance value of the first filter capacitor.

7. The radio-frequency power amplifier according to claim 1, wherein the direct current power module comprises a linear voltage regulator chip, an input filter capacitor, a third resistor, a fourth resistor, a fifth resistor, and a sixth resistor;
an input terminal of the linear voltage regulator chip is connected to a first power supply, and an output terminal of the linear voltage regulator chip is connected to the first filter capacitor;
the input filter capacitor is connected to the input terminal of the linear voltage regulator chip; and
the third resistor, the fourth resistor, the fifth resistor, and the sixth resistor are connected in series between the output terminal of the linear voltage regulator chip and a ground terminal, a common connection point of the fifth resistor and the sixth resistor is connected to a feedback input terminal of the linear voltage regulator chip, the fourth resistor is an adjustable resistor, and the fifth resistor is a thermistor.

8. The radio-frequency power amplifier according to claim 1, wherein the direct current power module comprises an operational amplifier, a first input filter capacitor, a transistor, a seventh resistor, an eighth resistor, a ninth resistor, a tenth resistor, and an eleventh resistor;
the first input filter capacitor is connected to a non-inverting input terminal of the operational amplifier;
the seventh resistor, the eighth resistor, and the ninth resistor are connected in series between a first power supply and a ground terminal, a common connection point of the eighth resistor and the ninth resistor is electrically connected to the non-inverting input terminal of the operational amplifier to provide a reference voltage to the non-inverting input terminal of the operational amplifier, the eighth resistor is an adjustable resistor, and the ninth resistor is a thermistor;
the tenth resistor is connected between an inverting input terminal of the operational amplifier and a ground terminal;
the eleventh resistor is connected between an emitter of the transistor and a first end of the tenth resistor; and
a base of the transistor is connected to an output terminal of the operational amplifier, a collector of the transistor is connected to the first power supply, and the emitter of the transistor is connected to the first filter capacitor.

9. The radio-frequency power amplifier according to claim 1, wherein the radio-frequency power amplification module comprises an input matching and direct current isolation circuit, an output matching and direct current isolation circuit, a field-effect transistor, and a second inductor; and
the input matching and direct current isolation circuit is connected between a radio frequency pulse signal input terminal and a gate of the field-effect transistor, the second inductor is connected between a first electrode of the field-effect transistor and a second power supply, the output matching and direct current isolation circuit is connected between a radio frequency pulse signal output terminal and the first electrode of the field-effect transistor, a second electrode of the field-effect transistor is connected to a ground terminal, and the gate of the field-effect transistor serves as the bias input terminal.

10. The radio-frequency power amplifier according to claim 1, wherein the radio frequency pulse signal comprises pulses of a fixed sequence and pulses of a variable sequence.

11. The radio-frequency power amplifier according to claim 5, wherein a capacitance value of the decoupling capacitor is less than the capacitance value of the first filter capacitor.

12. The radio-frequency power amplifier according to claim 2, wherein the direct current power module comprises a linear voltage regulator chip, an input filter capacitor, a third resistor, a fourth resistor, a fifth resistor, and a sixth resistor;
an input terminal of the linear voltage regulator chip is connected to a first power supply, and an output terminal of the linear voltage regulator chip is connected to the first filter capacitor;
the input filter capacitor is connected to the input terminal of the linear voltage regulator chip; and
the third resistor, the fourth resistor, the fifth resistor, and the sixth resistor are connected in series between the output terminal of the linear voltage regulator chip and a ground terminal, a common connection point of the fifth resistor and the sixth resistor is connected to a feedback input terminal of the linear voltage regulator chip, the fourth resistor is an adjustable resistor, and the fifth resistor is a thermistor.

13. The radio-frequency power amplifier according to claim 3, wherein the direct current power module comprises a linear voltage regulator chip, an input filter capacitor, a third resistor, a fourth resistor, a fifth resistor, and a sixth resistor;
an input terminal of the linear voltage regulator chip is connected to a first power supply, and an output terminal of the linear voltage regulator chip is connected to the first filter capacitor;
the input filter capacitor is connected to the input terminal of the linear voltage regulator chip; and
the third resistor, the fourth resistor, the fifth resistor, and the sixth resistor are connected in series between the output terminal of the linear voltage regulator chip and a ground terminal, a common connection point of the fifth resistor and the sixth resistor is connected to a feedback input terminal of the linear voltage regulator chip, the fourth resistor is an adjustable resistor, and the fifth resistor is a thermistor.

14. The radio-frequency power amplifier according to claim 4, wherein the direct current power module comprises a linear voltage regulator chip, an input filter capacitor, a third resistor, a fourth resistor, a fifth resistor, and a sixth resistor;
an input terminal of the linear voltage regulator chip is connected to a first power supply, and an output terminal of the linear voltage regulator chip is connected to the first filter capacitor;
the input filter capacitor is connected to the input terminal of the linear voltage regulator chip; and
the third resistor, the fourth resistor, the fifth resistor, and the sixth resistor are connected in series between the output terminal of the linear voltage regulator chip and a ground terminal, a common connection point of the fifth resistor and the sixth resistor is connected to a feedback input terminal of the linear voltage regulator chip, the fourth resistor is an adjustable resistor, and the fifth resistor is a thermistor.

15. The radio-frequency power amplifier according to claim 5, wherein the direct current power module comprises a linear voltage regulator chip, an input filter capacitor, a third resistor, a fourth resistor, a fifth resistor, and a sixth resistor;
an input terminal of the linear voltage regulator chip is connected to a first power supply, and an output terminal of the linear voltage regulator chip is connected to the first filter capacitor;
the input filter capacitor is connected to the input terminal of the linear voltage regulator chip; and
the third resistor, the fourth resistor, the fifth resistor, and the sixth resistor are connected in series between the output terminal of the linear voltage regulator chip and a ground terminal, a common connection point of the fifth resistor and the sixth resistor is connected to a feedback input terminal of the linear voltage regulator chip, the fourth resistor is an adjustable resistor, and the fifth resistor is a thermistor.

16. The radio-frequency power amplifier according to claim 2, wherein the direct current power module comprises an operational amplifier, a first input filter capacitor, a transistor, a seventh resistor, an eighth resistor, a ninth resistor, a tenth resistor, and an eleventh resistor;
the first input filter capacitor is connected to a non-inverting input terminal of the operational amplifier;
the seventh resistor, the eighth resistor, and the ninth resistor are connected in series between a first power supply and a ground terminal, a common connection point of the eighth resistor and
the ninth resistor is electrically connected to the non-inverting input terminal of the operational amplifier to provide a reference voltage to the non-inverting input terminal of the operational amplifier, the eighth resistor is an adjustable resistor, and the ninth resistor is a thermistor;
the tenth resistor is connected between an inverting input terminal of the operational amplifier and a ground terminal;
the eleventh resistor is connected between an emitter of the transistor and a first end of the tenth resistor; and
a base of the transistor is connected to an output terminal of the operational amplifier, a collector of the transistor is connected to the first power supply, and the emitter of the transistor is connected to the first filter capacitor.

17. The radio-frequency power amplifier according to claim 3, wherein the direct current power module comprises an operational amplifier, a first input filter capacitor, a transistor, a seventh resistor, an eighth resistor, a ninth resistor, a tenth resistor, and an eleventh resistor;
the first input filter capacitor is connected to a non-inverting input terminal of the operational amplifier;
the seventh resistor, the eighth resistor, and the ninth resistor are connected in series between a first power supply and a ground terminal, a common connection point of the eighth resistor and the ninth resistor is electrically connected to the non-inverting input terminal of the operational amplifier to provide a reference voltage to the non-inverting input terminal of the operational amplifier, the eighth resistor is an adjustable resistor, and the ninth resistor is a thermistor;
the tenth resistor is connected between an inverting input terminal of the operational amplifier and a ground terminal;
the eleventh resistor is connected between an emitter of the transistor and a first end of the tenth resistor; and
a base of the transistor is connected to an output terminal of the operational amplifier, a collector of the transistor is connected to the first power supply, and the emitter of the transistor is connected to the first filter capacitor.

18. The radio-frequency power amplifier according to claim 4, wherein the direct current power module comprises an operational amplifier, a first input filter capacitor, a transistor, a seventh resistor, an eighth resistor, a ninth resistor, a tenth resistor, and an eleventh resistor;
the first input filter capacitor is connected to a non-inverting input terminal of the operational amplifier;
the seventh resistor, the eighth resistor, and the ninth resistor are connected in series between a first power supply and a ground terminal, a common connection point of the eighth resistor and the ninth resistor is electrically connected to the non-inverting input terminal of the operational amplifier to provide a reference voltage to the non-inverting input terminal of the operational amplifier, the eighth resistor is an adjustable resistor, and the ninth resistor is a thermistor;
the tenth resistor is connected between an inverting input terminal of the operational amplifier and a ground terminal;
the eleventh resistor is connected between an emitter of the transistor and a first end of the tenth resistor; and
a base of the transistor is connected to an output terminal of the operational amplifier, a collector of the transistor is connected to the first power supply, and the emitter of the transistor is connected to the first filter capacitor.

19. The radio-frequency power amplifier according to claim 5, wherein the direct current power module comprises an operational amplifier, a first input filter capacitor, a transistor, a seventh resistor, an eighth resistor, a ninth resistor, a tenth resistor, and an eleventh resistor;
the first input filter capacitor is connected to a non-inverting input terminal of the operational amplifier;
the seventh resistor, the eighth resistor, and the ninth resistor are connected in series between a first power supply and a ground terminal, a common connection point of the eighth resistor and the ninth resistor is electrically connected to the non-inverting input terminal of the operational amplifier to provide a reference voltage to the non-inverting input terminal of the operational amplifier, the eighth resistor is an adjustable resistor, and the ninth resistor is a thermistor;
the tenth resistor is connected between an inverting input terminal of the operational amplifier and a ground terminal;
the eleventh resistor is connected between an emitter of the transistor and a first end of the tenth resistor; and
a base of the transistor is connected to an output terminal of the operational amplifier, a collector of the transistor is connected to the first power supply, and the emitter of the transistor is connected to the first filter capacitor.

20. The radio-frequency power amplifier according to claim 2, wherein the radio-frequency power amplification module comprises an input matching and direct current isolation circuit, an output matching and direct current isolation circuit, a field-effect transistor, and a second inductor; and
the input matching and direct current isolation circuit is connected between a radio frequency pulse signal input terminal and a gate of the field-effect transistor, the second inductor is connected between a first electrode of the field-effect transistor and a second power supply, the output matching and direct current isolation circuit is connected between a radio frequency pulse signal output terminal and the first electrode of the field-effect transistor, a second electrode of the field-effect transistor is connected to a ground terminal, and the gate of the field-effect transistor serves as the bias input terminal.
